(19) United States
(12) Patent Application Publication
(10) Pub. No.: US 2011/0170661 A1
(43) Pub. Date: Jul. 14, 2011

(54) INSPECTION SYSTEM AND METHOD

(75) Inventors: Clifford Bueno, Clifton Park, NY (US); William Robert Ross, Rotterdam, NY (US); Forrest Frank Hopkins, Cohoes, NY (US); Joseph Bendahan, San Jose, CA (US); Donald Earl Castleberry, Niskayuna, NY (US); Douglas Albagli, Clifton Park, NY (US); Robert August Kaucic, Niskayuna, NY (US); Jeffery Jon Shaw, Ballston Lake, NY (US); William Macomber Leue, Albany, NY (US)

(73) Assignee: GENERAL ELECTRIC COMPANY, SCHENECTADY, NY (US)

(21) Appl. No.: 12/198,469

(22) Filed: Aug. 26, 2008

(51) Int. Cl. G01N 23/04; H05K 13/00

(52) U.S. Cl. 378/57; 250/358.1; 29/592.1

(57) ABSTRACT

An inspection system is provided. The inspection system includes at least one source configured to emit a beam of radiation onto an object. The inspection system also includes at least two area detectors having different characteristics configured to receive a reflected beam of radiation from the object and output a plurality of image data streams corresponding to the different characteristics, wherein the at least two area detectors disposed in at least one of a cascaded arrangement or separated by a pre-determined distance along a direction parallel or perpendicular to a scan direction of the object.

### STATEMENT REGARDING FEDERALLY SPONSORED RESEARCH OR DEVELOPMENT

This invention was made with Government support under contract HSHQDC-07-C-00036 awarded by the Department of Homeland Security. The Government has certain rights in this invention.

### BACKGROUND

The invention relates generally to non-destructive inspection systems, and more particularly to inspection systems employing radiation detectors.

Inspection systems commonly employ radiographic imaging to detect contraband or the like in security applications, wherein a photographic image of an opaque sample is produced by transmitting a beam of radiation through the sample onto an electronic detector. The electronic detector senses an amount of radiation passing through the specimen and generates corresponding signals that are processed to form an image that is displayed on an electronic device, such as a cathode ray tube or flat panel display.

Various mathematical and analytical tools available to process generated data from the detectors have revolutionized electronic image detection. Typically, radiography systems employ large area detectors for enhanced detection. The detection of contraband together with position sensing over relatively large areas has generally required rather expensive two-dimensional arrays of detectors. The use of such two-dimensional arrays also requires complex position-sensing circuitry for use with such arrays in order to achieve good resolution of the impingement location.

Semiconductor detectors have generally been very useful for particulate radiation, because the range of the particles is usually less than a depletion region depth of the detectors. Such detectors have good energy resolution, excellent timing characteristics, good stability and simplicity of operation. However, the detectors often do not provide a desired signal-to-noise ratio or dynamic range required for x-ray inspection systems, particularly where x-rays of energies higher than ˜100 keV are involved. Furthermore, inspection systems employing such detectors are unable to distinguish between materials and material densities in a container, for example, to a desirable extent.

Therefore, an improved detection system is desirable.

### BRIEF DESCRIPTION

In accordance with an embodiment of the invention, an inspection system is provided. The inspection system includes at least one source configured to emit a beam of radiation onto an object. The inspection system also includes at least two area detectors having different characteristics configured to receive a transmitted beam of radiation from the object and output a plurality of image data streams corresponding to the different characteristics, the at least two area detectors disposed in at least one of a cascaded arrangement or separated by a pre-determined distance along a direction parallel or perpendicular to a scan direction of the object.

In accordance with another embodiment of the invention, a method for manufacturing an inspection system is provided. The method includes providing at least one source configured to emit a beam of radiation onto an object. The method also includes providing at least two area detectors having different characteristics configured to receive a transmitted beam of radiation from the object and output a plurality of image data streams corresponding to the different characteristics, wherein the at least two area detectors are disposed in at least one of a cascaded arrangement or separated by a pre-determined distance along a direction parallel or perpendicular to a scan direction of the object.

In accordance with another embodiment of the invention, an inspection system is provided. The inspection system includes at least one source configured to emit a beam of radiation onto an object. The inspection system also includes at least two area detectors including at least one scintillator having a thickness between about 0.1 mm to about 30 mm. The area detectors further have different characteristics configured to receive a transmitted beam of radiation from the object and output a plurality of image data streams corresponding to the different characteristics, the at least two area detectors disposed in at least one of a cascaded arrangement or separated by a pre-determined distance along a direction parallel or perpendicular to a scan direction of the object.

These and other advantages and features will be more readily understood from the following detailed description of preferred embodiments of the invention that is provided in connection with the accompanying drawings.

### DRAWINGS

FIG. 1 is a diagrammatic illustration of an exemplary cargo inspection system in accordance with an embodiment of the invention.

FIG. 2 is a perspective view of a gantry employed in the inspection system of FIG. 1 in accordance with an embodiment of the invention.

FIG. 3 is a diagrammatic illustration of an exemplary detector array employed in the gantry of FIG. 2 in accordance with an embodiment of the invention;

FIG. 4 is a block schematic diagram of an exemplary method employing shift and add algorithm for improving the signal-to-noise ratio of an output image from the inspection system of FIG. 1.

FIG. 5 is a flow chart representing steps in a method for manufacturing an inspection system in accordance with an embodiment of the invention.

### DETAILED DESCRIPTION

As discussed in detail below, embodiments of the invention include an imaging system and method including at least two area detectors having different characteristics. As used herein, the term ‘characteristics’ refers to a least one of an electronic gain, energy detection efficiency, particle type detection, or a spatial resolution. Such detectors provide multiple data streaming employing a single radiation beam. Further, the detectors are disposed in a cascaded arrangement or separated by a pre-determined distance. An embodiment of the invention provides two such area x-ray detectors for single or multiple-energy radiographic inspection of cargo containers. The detectors arranged in such a manner significantly improve detection capability for items of interest. It will be appreciated that, although the detectors have been illustrated herein to be employed in a cargo inspection system, the detectors may be employed in various non-limiting applications such as, for example, medical imaging applications, non-destructive testing applications, and security applications.

As used herein, the phrase “cargo container” refers to any cargo containment means, such as intermodal cargo containers, crates or boxes within which cargo is disposed, and pallets or skids upon which cargo may be disposed and secured, for example. Further, it is contemplated that such cargo containers may be transported via any appropriate shipment mode, such as by air, sea, or land, and associated with trucks as well as trains, for example. As used herein, the term “item(s) of interest” represents any item shipped via cargo container that may be desired to be identified, such as, but not limited to, Special Nuclear Material (SNM), radiological material, explosives, weapons, drugs, cigarettes, and alcohol. In an embodiment, the area detectors are used to detect items of interest having a high atomic number, also herein referred to as high Z-material, or other high-density material included to attempt to shield from detection SNM and radiological materials within the cargo container. In another embodiment, the area detectors are used to detect items of interest based upon an unexpected density variation or gradient, such as to detect drugs, explosives or other contraband within a cargo container.

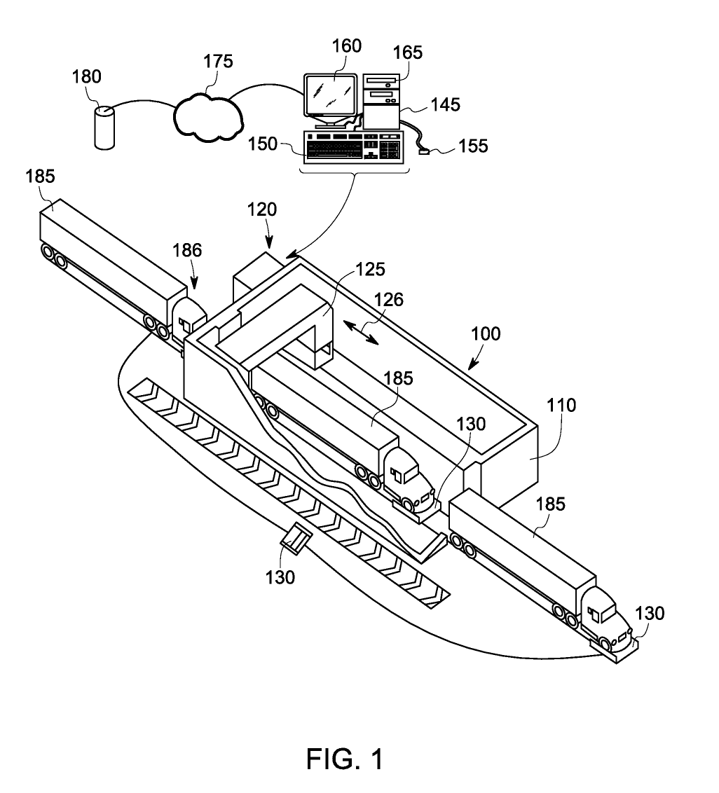

FIG. 1 is a perspective view of an inspection system 100 is depicted. The inspection system 100 includes an enclosure 110, such as a building, to control, via shielding for example, a radiation level outside the building 110 resulting from the inspection process therein. In a particular embodiment, the building 110 includes an office 120, a support 125, such as a mobile gantry, also herein referred to as a gantry, and a set of truck-towing platforms 130. Within the office 120 is a processor 145, such as a computer, in signal communication with the gantry 125 and the set of towing platforms 130. The processor 145 includes input devices 150, 155, such as a keyboard and mouse, an output device 160, such as a display screen, and a program storage device 165, such as a hard disk drive, for example. The program storage device 165 includes a program executing on the processor 145 for performing a method of inspecting a cargo container 185 and improving a signal-to-noise ratio of cargo container 185 inspection images. The processor 145 may be in signal connection with a network 175, such as through the Internet or an intranet, for example that is in further connection with a database 180 that stores information associated with the inspection of cargo containers 185. Such information may include inspection results, shipment manifest, point of origin, and other information that may be associated with the containers 185.

In an embodiment, the truck-towing platforms 130 are responsive to the processor 145 to convey trucks 186 into, through, and/or out of the building 110. The utilization of at least one of the truck-towing platforms 130 and the mobile gantry 125 create a pipeline of the containers 185, allowing performance of various processes in parallel with other processes, thereby preventing “waiting” periods that reduce the throughput. The use of the towing platforms 130 allows for increased throughput by eliminating a delay associated with an exit by a driver from the building 110. The mobile gantry 125 is responsive to control signals provided by the processor 145 to scan the container 185 at variable speed, forward and backward. The mobile gantry 125 further allows a more detailed, or “target” scan to be performed in response to possible discovery of items of interest.

While an embodiment has been described having truck-towing platforms 130 to convey the trucks 186 into, through, and/or out of the building 110, it will be appreciated that the scope of the embodiment is not so limited, and that the embodiment will also apply to inspection systems 100 that include other container 185 movement arrangements, such as container support platforms to convey the container 185 into, through, and/or out of the building 110, to have the driver drive the truck 186 into, through, and/or out of the building 110, and to incorporate the building 110 surrounding a railroad track, for example.

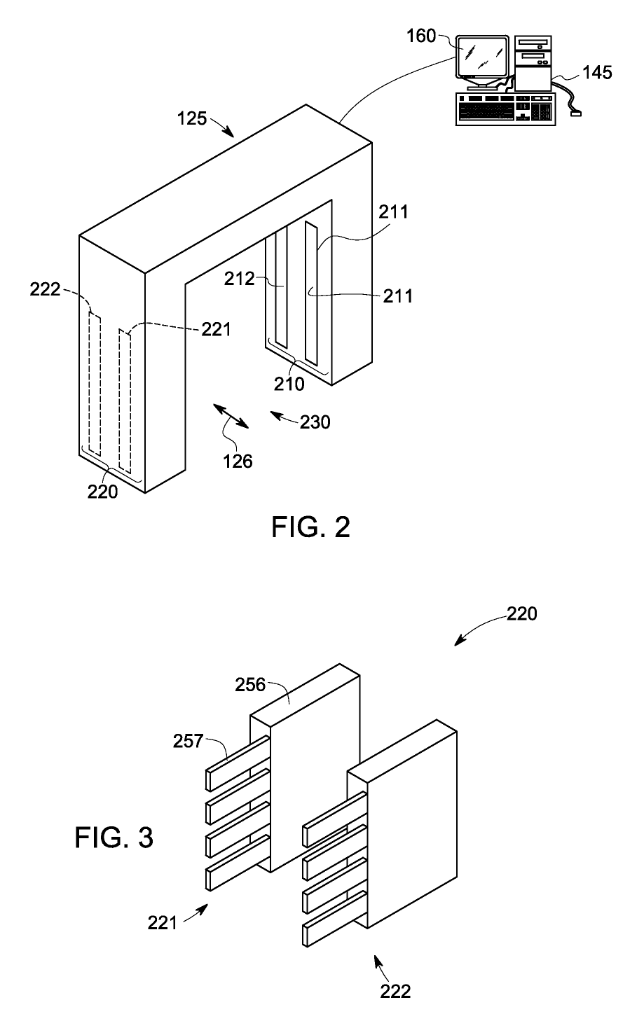

Referring now to FIG. 2, a top perspective view of the gantry 125 of FIG. 1 is depicted. The gantry 125 includes at least one radiation detector array 220, such as a large area X-ray detector (LAXD). In another embodiment, the radiation detector array 220 is a linear detector array. In one embodiment, the gantry 125 also includes at least one radiation source 210, such as, but not limited to, an x-ray source. In a particular embodiment, the radiation source 210 includes a linear accelerator to generate a beam of x-rays. The radiation source 210 and radiation detector array 220 are opposingly disposed so as to be separated by an inspection cavity 230, dimensioned to surround and allow movement of the container 185 therethrough. The radiation source 210 is in signal communication with and responsive to the processor 145 to transmit a radiation beam directed toward the radiation detector 220 to pass through the container 185. The radiation beam passing through the container 185 is attenuated in response to material characteristics of contents within the container 185. After passing through and becoming attenuated by the container 185, the detector 220 receives the attenuated radiation beam. The detector 220 receives, or detects, the attenuated radiation beam and produces a set of electrical signals responsive to the intensity of the attenuated radiation beam. It will be appreciated that in response to motion of at least one of the container 185 and the gantry 125, the set of electrical signals vary along a length, as defined by a travel axis 126, of the container 185. The set of electrical signals is made available to the processor 145, which executes a reconstruction program to interpret and represent the set of electrical signals as an image data set to be further analyzed, and displayed upon the display screen 160.

In an embodiment, the processor 145 is receptive of and responsive to a screening that provides the set of electrical signals (also herein referred to as a screening detector signal) in response to transmission of a screening radiation beam, such as a screening x-ray beam. The transmission of the screening x-ray beam is along a length, or screening portion of the container 185. The processor 145, upon obtaining information from the screening, creates an image data set for displaying upon the display screen 160 images of the screening portion of the container 185. The processor 145 further analyzes the image data set to determine a likelihood of a presence of an item of interest, such as an item having at least one of high-Z material, and shielding material that may affect the ability of the screening x-ray beam from the source 210 to adequately penetrate the container 185 and be detected by the detector 220, for example. For example, the processor 145 may analyze the image data set to identify an unusual or unexpected density gradient, or the processor 145 may analyze the screening detector signal to determine if the screening detector signal is in excess of a threshold value. In response to the processor 145 determining a likelihood of a presence of items of interest within the container 185, the processor 145 identifies one or more target portions of the container 185 that are likely to contain the items of interest.

Subsequent to transmission of the target x-ray beam, the processor 145 is receptive of and responsive to a set of target electrical signals provided by the detector 220 corresponding to the detected attenuated target x-ray beam. An image data set is created for displaying upon the display screen 160 images of the target portion of the container 185. The processor 145 further analyzes the image data set created from the target electrical signals to determine a presence or absence of the items of interest within the cargo container 185. The processor 145 is further configured to generate one of a first signal indicative of the presence of the item of interest or a second signal indicative of the absence of the item of interest.

In an embodiment, the gantry 125 includes a low energy radiation source 211, such as a low energy x-ray source, and a high-energy radiation source 212, such as a high-energy x-ray source also herein respectively referred to as a first and a second radiation source 211, 212. The first and second radiation sources 211, 212 provide a set of multiple energy radiation beams, such as a set of multiple-energy x-ray beams. In an embodiment, the set of multiple-energy radiation beams is a dual-energy x-ray beam. The gantry 125 also includes two detector arrays 221, 222 described in detail in FIG. 3. The first x-ray source 211 generates one energy distribution of x-rays and the second x-ray source 212 generates another energy distribution of x-rays. The processor 145 is receptive of and responsive to the different electrical signals provided by the detector arrays 221, 222 in response to the detection of the multiple-energy x-ray beams from the x-ray sources 211, 212. The processor 145 provides an image of the container 185 contents via a technique known in the art as energy discrimination or dual-energy imaging. It will be appreciated that in response to a variation in material responses to different energy distributions, the energy discrimination imaging provided by the processor 145 distinguishes between different materials that may possess similar densities. As disclosed herein, the gantry 125 includes the first and second x-ray sources 211, 212 and provides the ability to identify the target portions of the container 185 as necessary to provide adequate detection accuracy.

In one embodiment, the image data set is analyzed in real time to minimize the time to produce an alarm decision by the processor 145, such as in response to the processor 145 determining that the image data set created from the target signals indicates a likelihood of a presence of items of interest. Alternatively, the image data set of the container 185 is displayed upon the display screen 160 with a minimal delay resulting from the necessary time to process the image data set into a visual image, thereby allowing an operator to start inspecting the images before the scan is completed.

In an embodiment, identified target portions of the container 185 that the processor 145 has determined may include the items of interest are presented to the operator via the display 160 of the processor 145. The operator can employ an image viewer to analyze a resulting image with a variety of image viewing and manipulation tools included with the reconstruction program executing on the processor 145. Operating procedures will instruct the operator to either clear the alarm based upon analysis of the images and release the truck 186, or to follow further alarming resolution procedures, such as devanning to remove the cargo from the container 185 for further inspection.

FIG. 3 is a diagrammatic illustration of an exemplary arrangement of the array 220 of area detectors (FIG. 2) having different characteristics. In the illustrated embodiment, two area detectors 221, 222 (FIG. 2) are separated in space by a pre-determined distance. In a non-limiting example, the pre-determined distance is between about 0.5 mm to about 2 mm. It will be appreciated that in another embodiment, the detectors 221, 222 may be disposed in a cascaded arrangement one essentially in front of the other, whereby a given ray path of a radiation beam passes through both detectors. As illustrated herein, the area detectors 221, 222 include a radiation detection material 256 with electronics 257 including, for example, control electronics pulled out so as not to affect the active area of the detectors. Such a design also enables overlaying of the detectors in a cascaded arrangement. Further, the number of detectors employed may be more than two. Multiple detectors employed in aforementioned arrangements allow for a faster imaging time to cover the range of material density present. In one embodiment, one of the detectors 221, for example, is a neutron detector and the other detector 222, is an X-ray detector. In a particular embodiment, one of the area detectors is configured so as to detect the low energy x-rays in a polychromatic spectrum, while the other detector is configured to detect the higher energy x-rays in a polychromatic spectrum, providing a dynamic dual-energy imaging capability in either a side-by-side or a cascaded geometry. In another particular embodiment, one of the area detectors 221 is of a high gain enabling capture of low signals through for example, thick and dense regions of the cargo container 185 (FIG. 1) while the other detector 222 is of a low gain enabling capture of high signals generated in a scenario such as, but not limited to, a relatively empty container 185.

In one embodiment, image streams from both the detectors 221, 222 are combined with perfect registration by various techniques such that a resultant signal with a higher signal-to-noise ratio than that with either detector alone is obtained. In another embodiment, the image streams are processed as separate data streams. In an exemplary embodiment, the area detectors 221, 222 include an amorphous silicon photodetector as a light receiver from a scintillator, luminescent material or phosphor or as an electron receiver from a photoconductive material. In another embodiment, the area detectors 221, 222 include at least one of a glass, ceramic, crystalline, or polycrystalline scintillator such as, but not limited to, crystalline cesium iodide activated with thallium (CsI:Tl) and grown as fine needles, or polycrystalline particles of gadolinium oxysulfide activated with terbium (GOS:Tb) and configured with a binder into a phosphor sheet, a photoconductor such as, but not limited to, cadmium telluride (CdTe), or a combination thereof. The use of GOS:Tb or CdTe also offer high neutron cross-section, and may be used with its appropriate read structure as one of a neutron detector in a multi-detector arrangement. In an exemplary embodiment, the scintillator has a thickness in a range between about 0.1 mm to about 30 mm.

In yet another embodiment, the area detectors 221, 222 may be vertically disposed with respect to each other, wherein the detector on top with a different gain detects open space mostly in a cargo container where the top 2-3 feet is empty. In an exemplary embodiment, filters may be employed in front of each of the detectors to further separate different energies captured.

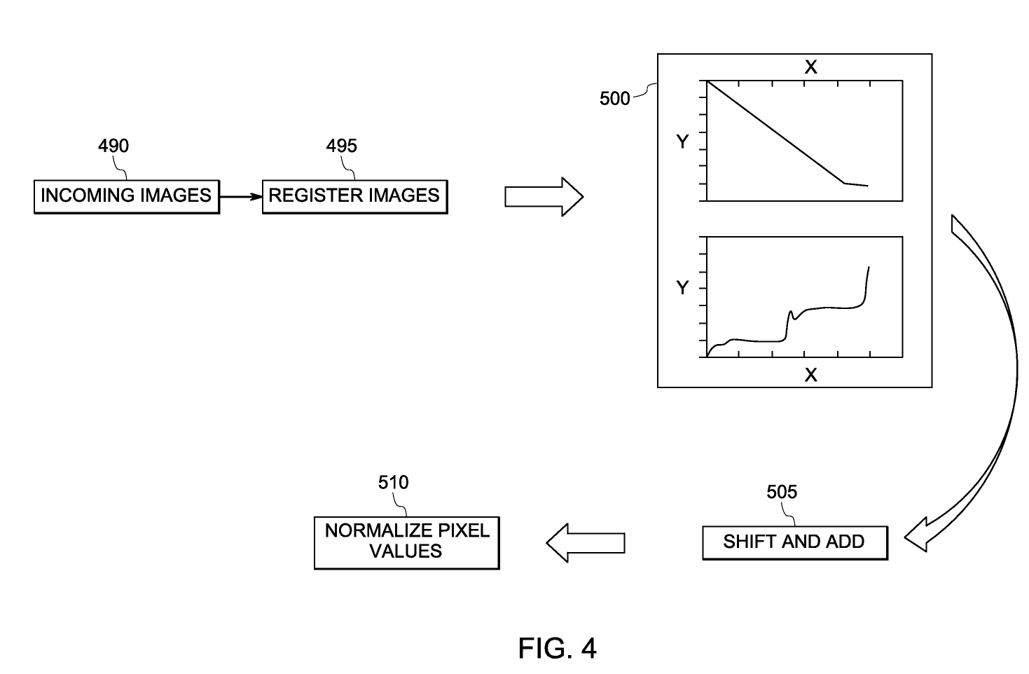

FIG. 4 depicts an exemplary embodiment of block schematic diagram of the shift and add signal processing method for improving the signal-to-noise ratio (SNR) of the image and stitching together multiple views of an object to present a composite image. The incoming images, represented by block 490 are registered, at block 495, to one another to provide a mapping, shown in block 500, between a same point on a same object seen in multiple views. It will be appreciated that the registration is accomplished using hardware techniques or software algorithms, for example. After registration, improved SNR can be achieved by accumulating (block 505) the flux associated with each pixel and normalizing, shown in block 510, by dividing by the total number of times each pixel was exposed to radiation. A composite image, shown in block 515 can then be formed by stitching together the frames acquired during the translation of the container 185 or the source 210 and detector 220. In an embodiment using multiple energy inspection, the shift and add processing is performed separately for each energy, thereby providing enhanced detection of the atomic number of items of interest via the multi-energy imaging. One embodiment is to employ two separate sources, each directed to a detector configured for the energy or particle (neutron) deposited, where the detectors may be cascaded with perfect inherent registration, or adjacent, with object motion, and later registered by the shift and add methodology.

In an embodiment, the composite images provided by the shift and add temporal averaging are displayed on the display 160 (FIG. 1) to an operator of the system 100 as they become available. In one embodiment, a “live”, or real-time image of the container 185 is displayed on the display 160 immediately following reconstruction of the image data set (but prior to shift and add processing). It is contemplated that because such an image data set might provide low statistical data and corresponds to a large amount of data that is difficult to analyze, it would be useful to record this data for later playback at slower rates, where other window/level and zoom display processing can be achieved. Having a “video” playback with an area detector will also provide some 3D information on thickness and location of objects across the large area detectors, or multiple detectors. This stored image stream would be an adjunct to the shift and add composite data that is the primary means to evaluate the scan.

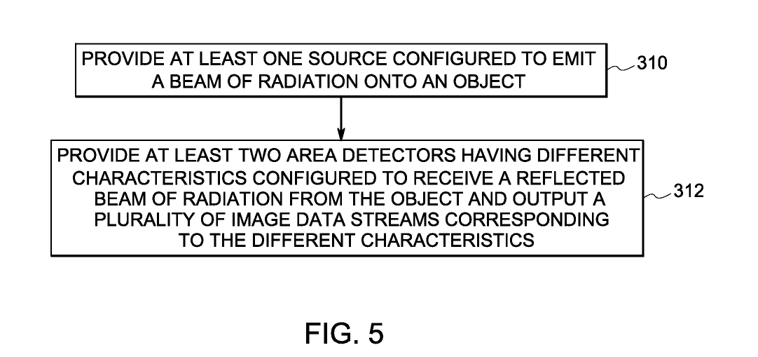

FIG. 5 is a flow chart representing steps in a method for manufacturing an imaging system. The method includes providing at least one source configured to emit a beam of radiation onto an object in step 310. In an exemplary embodiment, an x-ray source or a gamma source is provided. At least two area detectors having different characteristics configured to receive a transmitted beam of radiation from the object are provided in step 312. The at least two area detectors output multiple image streams corresponding to the different characteristics, wherein the at least two area detectors are disposed in at least one of a cascaded arrangement or separated by a predetermined distance along a direction parallel or perpendicular to a scan direction of the object. In a particular embodiment, the at least two area detectors include providing flat panel detectors. In one embodiment, a processing circuitry is provided that is configured to receive multiple image streams and overlay the image data streams to produce a perfectly registered image. In another embodiment, the processing circuitry overlays image data streams by employing a shift and add algorithm. In yet another embodiment, at least one filter is disposed before the at least two area detectors, wherein the at least one filter allows radiation corresponding to a pre-determined wavelength or energy range, or particle type.

The various embodiments of an inspection system and method described above provide a way to achieve a convenient and efficient means for material identification for various applications. The detectors employed in the described arrangement provide a desirable separation of energies or particles and also provide registration of images captured. The technique also improves parameters such as, but not limited to, dynamic range and signal-to-noise. The approach also may use detectors with differing spatial resolution and SNR, thus one data stream may provide very high spatial resolution, while the other detector provides high SNR, both obtained with a single source of radiation. In this case the data streams need not be registered, although high resolution features from one detector may be overlayed onto the high SNR image of the second detector. Furthermore, the system and technique allow for concurrent extraction of different parameters such as, but not limited to, energies and particles in cases wherein information pertaining to different parameters are embedded in a beam of radiation. All of the above provides a way to capture more information in a single scan, without having to move the cargo or other commerce into subsequent systems, or scanning modules. The system and technique also allow for safer and cost effective security means. Some of the non-limiting applications also include material differentiation in the oil and gas industry such as, detecting corrosion from metal in oil and gas pipelines and detecting organic sheet explosives from metallic bombs in a security application.

It is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

Furthermore, the skilled artisan will recognize the interchangeability of various features from different embodiments. For example, the use of a neutron detector with respect to one embodiment can be adapted for use with a cesium iodide scintillator described with respect to another. Similarly, the various features described, as well as other known equivalents for each feature, can be mixed and matched by one of ordinary skill in this art to construct additional systems and techniques in accordance with principles of this disclosure.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed as new and desired to be protected by Letters Patent of the United States is:

1. An inspection system, comprising:
at least one source configured to emit a beam of radiation onto an object; and
at least two area detectors having different characteristics configured to receive a transmitted beam of radiation from the object and output a plurality of image data streams corresponding to the different characteristics, the at least two area detectors disposed in at least one of a cascaded arrangement or separated by a predetermined distance along a direction parallel or perpendicular to a scan direction of the object.

2. The inspection system of claim 1, comprising a processing circuitry configured to:
receive the plurality of image data streams; and
overlay the image data streams to produce a perfectly registered image.

3. The system of claim 1, wherein the source comprises an X-ray source a gamma source, or a neutron source.

4. The system of claim 1, wherein the area detectors comprise a flat panel detector.

5. The system of claim 1, wherein the area detectors comprise at least one of silicon diode, a scintillator, a ceramic, crystal, or needle based scintillator, a photoconductor, or a combination thereof.

6. The system of claim 5, wherein the scintillator comprises glass, ceramic, crystalline or polycrystalline material.

7. The system of claim 6, wherein the crystalline material comprises a needle based crystalline material.

8. The system of claim 7, wherein the needle based crystalline material comprises cesium iodide.

9. The system of claim 5, wherein the photoconductor comprises cadmium telluride.

10. The system of claim 1, wherein the area detectors comprise an amorphous silicon detector.

11. The system of claim 1, wherein the different characteristics comprise an electronic gain, energy detection efficiency, particle type detection, or spatial resolution.

12. The system of claim 1, comprising at least one filter disposed before the at least two detectors, the at least one filter configured to allow radiation corresponding to a pre-determined wavelength range.

13. The system of claim 1, wherein the area detectors comprise neutron detectors or X-ray detectors.

14. The system of claim 2, wherein the processing circuitry employs a shift and add algorithm to overlay the image data streams.

15. The imaging system of claim 1, wherein the object comprises luggage, a human being, or a cargo container.

16. A method for manufacturing an inspection system, comprising:
providing at least one source configured to emit a beam of radiation onto an object; and
providing at least two area detectors having different characteristics configured to receive a reflected beam of radiation from the object and output a plurality of image data streams corresponding to the different characteristics, the at least two area detectors disposed in at least one of a cascaded arrangement or separated by a pre-determined distance along a direction parallel or perpendicular to a scan direction of the object.

17. The method of claim 16, comprising providing a processing circuitry configured to:
receive the plurality of image data streams; and
overlay the image data streams to produce a perfectly registered image.

18. The method of claim 16, wherein providing the at least two area detectors comprises providing flat panel detectors.

19. The method of claim 16, wherein said providing the processing circuitry configured to overlay the image data streams comprises employing a shift and add algorithm.

20. The method of claim 16, wherein said providing the processing circuitry configured to overlay the image data streams comprises employing a dual energy technique to provide material identification.

21. The method of claim 16, wherein providing at least one source comprises providing an X-ray source or a gamma source.

22. The method of claim 16, comprising disposing at least one filter before the at least two area detectors, the at least one filter configured to allow radiation corresponding to a pre-determined wavelength range.

23. An inspection system, comprising:
at least one source configured to emit a beam of radiation onto an object; and
at least two area detectors comprising at least one scintillator, the at least one scintillator comprising a thickness between about 0.1 mm to about 30 mm, the at least two area detectors having different characteristics configured to receive a transmitted beam of radiation from the object and output a plurality of image data streams corresponding to the different characteristics, the at least two area detectors disposed in at least one of a cascaded arrangement or separated by a pre-determined distance along a direction parallel or perpendicular to a scan direction of the object.

24. The system of claim 23, wherein the scintillator comprises cesium iodide deposited on a read out device.

25. The system of claim 24, wherein the read out device comprises an amorphous silicon diode photodiode.
